(19) United States
(12) Patent Application Publication
(10) Pub. No.: US 2024/0300379 A1
(43) Pub. Date: Sep. 12, 2024

(54) BATTERY MANAGEMENT METHOD AND APPARATUS, AND COMPUTER-READABLE STORAGE MEDIUM

(71) Applicant: BYD COMPANY LIMITED, Shenzhen (CN)

(72) Inventors: Linwang DENG, Shenzhen (CN); Xiaoqian LI, Shenzhen (CN); Tianyu FENG, Shenzhen (CN); Jingjing HONG, Shenzhen (CN)

(21) Appl. No.: 18/669,524

(22) Filed: May 21, 2024

Related U.S. Application Data
(63) Continuation of application No. PCT/CN2022/135668, filed on Nov. 30, 2022.

(30) Foreign Application Priority Data
Dec. 30, 2021 (CN) 202111681358.1

(51) Int. Cl. B60L 58/14; H01M 10/42; H02J 7/00

(52) U.S. Cl. CPC B60L 58/14; H01M 10/425; H02J 7/0047; H02J 7/00712; H01M 2010/4271; H01M 2220/20

(57) ABSTRACT

A battery management method includes: obtaining a current high-voltage inflection point power value of each cell; obtaining a current historical cumulative balance power value of each cell; obtaining a current equivalent self-discharge value of each cell through calculation; obtaining an equivalent self-discharge value at a previous moment of each cell; obtaining a target equivalent self-discharge value of each cell through calculation; determining a maximum target equivalent self-discharge value and a minimum target equivalent self-discharge value; obtaining a maximum equivalent self-discharge rate and a minimum equivalent self-discharge rate through calculation; and when a difference between the maximum equivalent self-discharge rate and the minimum equivalent self-discharge rate is greater than a preset threshold, managing a target cell corresponding to the maximum target equivalent self-discharge value.

### CROSS-REFERENCE TO RELATED APPLICATIONS

The present application is a continuation application of PCT application No. PCT/CN2022/135668, filed on Nov. 30, 2022, which claims priority to Chinese Patent Application No. 202111681358.1, entitled “BATTERY MANAGEMENT METHOD AND MANAGEMENT APPARATUS, VEHICLE, AND COMPUTER-READABLE STORAGE MEDIUM” and filed on Dec. 30, 2021, content of all of which is incorporated herein by reference in its entirety.

### FIELD

The present disclosure relates to the field of battery technologies, and more

specifically, to a battery management method and management apparatus, and a computer-readable storage medium.

### BACKGROUND

Power batteries are widely used in the fields of electric vehicle power sources and backup power sources. To increase energy and a voltage of the power batteries, several cells need to be connected in series to form a power battery pack for use. However, in a process of producing the cells, due to a production process, a self-discharge rate of each cell is different. The difference in the self-discharge rates leads to inconsistent states of charge of the cells, making each cell unable to be synchronously charged to an upper limit voltage or discharged to a lower limit voltage, which affects a capacity of an entire power battery pack. In view of this, self-discharge power of each cell needs to be detected to identify cells with a larger deviation of the self-discharge power.

Currently, detection of self-discharge of the cells is performed before leaving a factory. Specifically, before leaving the factory, the self-discharge rates of the cells are detected, and the cells with basically the same self-discharge rates are assembled into the power battery pack. However, with the use and aging of the power battery pack, the self-discharge rate of each cell changes. The foregoing self-discharge detection is only a test before leaving the factory, and the self-discharge of the power battery pack cannot be monitored during the use of the power battery pack.

### SUMMARY

To resolve the foregoing technical problems, the present disclosure provides a battery management method, a battery management apparatus, a vehicle, and a computer-readable storage medium, which can calculate a target equivalent self-discharge value of a cell during the use of the cell, and can promptly identify a cell with abnormal self-discharge and manage the abnormal cell.

A first aspect of the present disclosure provides a battery management method.

The battery management method includes: a current high-voltage inflection point power value corresponding to a high-voltage inflection point of a charging curve of each cell at a current moment is obtained; a current historical cumulative balance power value of each cell at the current moment is obtained; a current equivalent self-discharge value of the cell is obtained according to the current high-voltage inflection point power value of each cell and the current historical cumulative balance power value of the cell; an equivalent self-discharge value at a previous moment of each cell is obtained; the equivalent self-discharge value at the previous moment of the cell is subtracted from the current equivalent self-discharge value of each cell to obtain a target equivalent self-discharge value of the cell within an interval between the current moment and the previous moment; a maximum target equivalent self-discharge value and a minimum target equivalent self-discharge value among the target equivalent self-discharge values of all cells are determined; the maximum target equivalent self-discharge value is divided by the interval to obtain a maximum equivalent self-discharge rate, and the minimum target equivalent self-discharge value is divided by the interval to obtain a minimum equivalent self-discharge rate; and when it is determined that a difference between the maximum equivalent self-discharge rate and the minimum equivalent self-discharge rate is greater than a preset threshold, a target cell corresponding to the maximum target equivalent self-discharge value is managed.

A second aspect of the present disclosure further provides a battery management apparatus. The battery management apparatus includes: a number of cells, an obtaining module, and a processing module. The obtaining module is configured to obtain a current high-voltage inflection point power value corresponding to a high-voltage inflection point of a charging curve of each cell at a current moment, a current historical cumulative balance power value of each cell at the current moment, and an equivalent self-discharge value at a previous moment of each cell. The processing module is configured to obtain a current equivalent self-discharge value of the cell according to the current high-voltage inflection point power value of each cell and the current historical cumulative balance power value of the cell; subtract the equivalent self-discharge value at the previous moment of the cell from the current equivalent self-discharge value of each cell to obtain a target equivalent self-discharge value of the cell within an interval between the current moment and the previous moment; determine a maximum target equivalent self-discharge value and a minimum target equivalent self-discharge value among the target equivalent self-discharge values of all cells; divide the maximum target equivalent self-discharge value by the interval to obtain a maximum equivalent self-discharge rate, and divide the minimum target equivalent self-discharge value by the interval to obtain a minimum equivalent self-discharge rate; and when it is determined that a difference between the maximum equivalent self-discharge rate and the minimum equivalent self-discharge rate is greater than a preset threshold, manage a target cell corresponding to the maximum target equivalent self-discharge value.

A third aspect of the present disclosure further provides a vehicle. The vehicle includes the foregoing battery management apparatus.

A fourth aspect of the present disclosure further provides a computer-readable storage medium. The computer-readable storage medium stores a computer program, and the computer program is invoked by a processor to perform the foregoing battery management method.

The present disclosure provides a battery management method, a battery management apparatus, a vehicle, and a computer-readable storage medium. By obtaining the current high-voltage inflection point power value of the charging curve of each cell and the current historical cumulative balance power value, the current equivalent self-discharge value of each cell is obtained. The target equivalent self-discharge value of each cell is obtained by subtracting the equivalent self-discharge value at the previous moment from the current equivalent self-discharge value, so that self-discharge conditions of all cells are monitored during the use of the battery management apparatus. Then the maximum equivalent self-discharge rate and the minimum equivalent self-discharge rate are obtained through calculation by using the target equivalent self-discharge values of all cells, and when the difference between the maximum equivalent self-discharge rate and the minimum equivalent self-discharge rate is greater than the preset threshold, the target cell with the maximum equivalent self-discharge rate is managed, so that a user can promptly discover a cell with abnormal self-discharge to perform maintenance or replacement.

### BRIEF DESCRIPTION OF THE DRAWINGS

To describe the technical solutions in the present disclosure more clearly, the following briefly introduces the accompanying drawings for describing certain embodiments. Apparently, the accompanying drawings show some embodiments of the present disclosure, and a person of ordinary skill in the art may still derive other drawings from these accompanying drawings without creative efforts.

FIG. 1 is a flowchart of a battery management method according to an embodiment of the present disclosure.

FIG. 2 is a schematic diagram of a charging curve according to an embodiment of the present disclosure.

FIG. 3 is a schematic diagram of a voltage differential curve according to an embodiment of the present disclosure.

FIG. 4 is a sub-flowchart of step S103 in FIG. 1.

FIG. 5 is a block diagram of a structure of a battery management apparatus according to an embodiment of the present disclosure.

FIG. 6 is a block diagram of a structure of a vehicle according to an embodiment of the present disclosure.

Reference Numerals: 100—battery management apparatus; 10—obtaining module; 20—processing module; 30—communication module; 40—storage module; 200—vehicle; 50—cell; and 60—reminder module.

### DETAILED DESCRIPTION

The technical solutions in embodiments of the present disclosure are described

below with reference to the accompanying drawings. Apparently, the described embodiments are merely some rather than all of the embodiments of the present disclosure. Other embodiments obtained by a person of ordinary skill in the art based on the disclosed embodiments of the present disclosure without creative efforts shall fall within the protection scope of the present disclosure.

In descriptions of the present disclosure, unless otherwise explicitly specified or defined, the term “connection” should be understood in a broad sense. For example, the connection may be a fixed connection, a detachable connection, or an integral connection; the connection may be a direct connection, an indirect connection through an intermediary, or internal communication between two components; the connection may be a communication connection; or the connection may be an electrical connection. A person of ordinary skill in the art may understand specific meanings of the terms in the present disclosure according to specific situations.

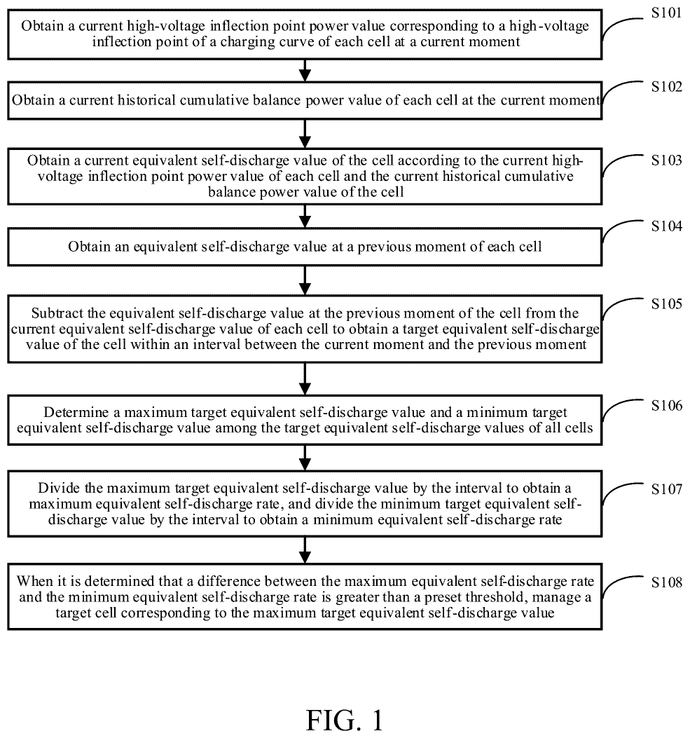

Refer to FIG. 1. FIG. 1 is a flowchart of a battery management method according to an embodiment of the present disclosure. The battery management method is applied to a battery management apparatus, and the battery management apparatus includes a number of cells. As shown in FIG. 1, the battery management method includes the following steps:

S101: A current high-voltage inflection point power value corresponding to a high-voltage inflection point of a charging curve of each cell at a current moment is obtained. A power value may refer to the amount of power of a cell.

S102: A current historical cumulative balance power value of each cell at the current moment is obtained.

S103: According to the current high-voltage inflection point power value of each cell and the current historical cumulative balance power value of the cell, a current equivalent self-discharge value of the cell is obtained.

S104: An equivalent self-discharge value at a previous moment of each cell is obtained.

S105: The equivalent self-discharge value at the previous moment of the cell is subtracted from the current equivalent self-discharge value of each cell to obtain a target equivalent self-discharge value within an interval between the current moment and the previous moment of the cell.

S106: A maximum target equivalent self-discharge value and a minimum target equivalent self-discharge value among the target equivalent self-discharge values of all cells are determined.

S107: The maximum target equivalent self-discharge value is divided by the interval to obtain a maximum equivalent self-discharge rate, and the minimum target equivalent self-discharge value is divided by the interval to obtain a minimum equivalent self-discharge rate.

S108: When it is determined that a difference between the maximum equivalent self-discharge rate and the minimum equivalent self-discharge rate is greater than a preset threshold, a target cell corresponding to the maximum target equivalent self-discharge value is managed.

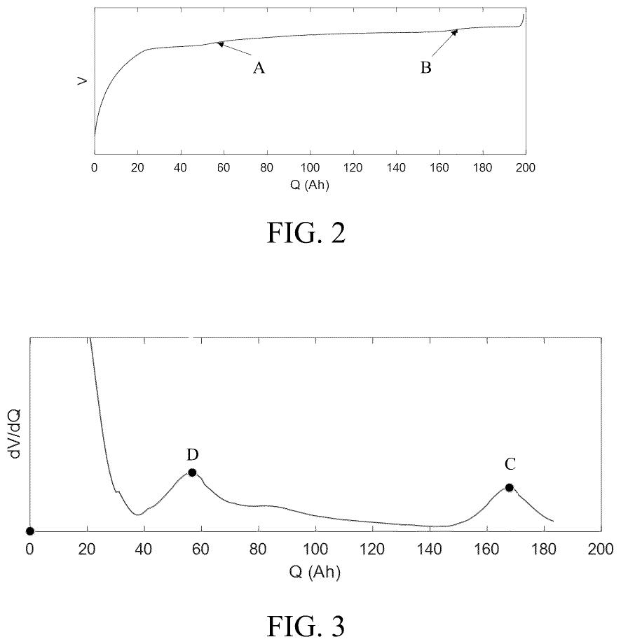

Refer to FIG. 2 and FIG. 3 together. FIG. 2 is a schematic diagram of a charging curve according to an embodiment of the present disclosure, and FIG. 3 is a schematic diagram of a voltage differential curve according to an embodiment of the present disclosure. All cells in the battery management apparatus are connected in series. When all cells are charged, a vehicle collects and records parameters of each cell in real time. The parameters include: a voltage, a current, a temperature, an SOC (state of charge), and the like. By performing data processing on the parameters, such as filtering, differentiation, integration, fitting, wavelet analysis, neural network operations, and the like, the charging curve of each cell may be obtained. As shown in FIG. 2, the charging curve is a voltage-power curve, that is, a relationship curve between a voltage and power. The voltage-power curve has three intervals at which the voltage changes relatively slowly. The interval at which the voltage changes relatively slowly is a voltage plateau region. A region in which the voltage changes relatively quickly exists between two adjacent voltage plateau regions. A point at which the voltage changes the fastest in the region in which the voltage changes relatively quickly is a voltage inflection point. The voltage-power curve has two voltage inflection points. The two voltage inflection points are a high-voltage inflection point (B in FIG. 2) and a low-voltage inflection point (A in FIG. 2). The high-voltage inflection point and the low-voltage inflection point respectively correspond to two maximum points (a maximum point C and a maximum point D) on the voltage differential curve (as shown in FIG. 3), where the high-voltage inflection point B corresponds to the maximum point C, and the low-voltage inflection point A corresponds to the maximum point D.

The current historical cumulative balance power value is a cumulative value of a balance power value obtained at the current moment and a balance power value obtained each time before the current moment.

In some embodiments, the equivalent self-discharge value at the previous moment of each cell is obtained by subtracting the historical cumulative balance power value at the previous moment of the cell from the high-voltage inflection point power value at the previous moment of each cell. The historical cumulative balance power value at the previous moment is a cumulative value of a balance power value obtained at the previous moment and a balance power value obtained each time before the previous moment.

During the use of the cell, the cell self-discharges due to current manufacturing processes. A self-discharge process of each cell is different, causing self-discharge rates of the number of cells to be inconsistent. Since the self-discharge process of the cell causes the high-voltage inflection point power value to deviate, and the self-discharge rates of the number of cells are inconsistent, the high-voltage inflection point power values of the number of cells deviate to different degrees, so that obtained high-voltage inflection point power values of all cells are different. To compensate for inconsistent remaining power of the cell due to the inconsistent self-discharge rates of the cell, the battery management apparatus may balance the number of cells. Specifically, remaining power of all cells are compared, and the cell with higher remaining power is discharged, so that the cell generates corresponding balance power. A smaller self-discharge quantity of the cell indicates more balance power generated. Therefore, the equivalent self-discharge value of the cell may be obtained through calculation by using the high-voltage inflection point power value and the historical cumulative balance power value of the cell. The equivalent self-discharge value is a relative self-discharge value. Since an absolute self-discharge value cannot be calculated, in the present disclosure, the equivalent self-discharge value is a relative self-discharge value of each cell.

In some embodiments, the previous moment is a moment at which the vehicle leaves a factory, the equivalent self-discharge value at the previous moment of each cell is 0, the historical cumulative balance power value at the previous moment of each cell is 0, and the high-voltage inflection point power value at the previous moment of each cell is 0.

In some embodiments, the current moment is a moment at which the charging curve is obtained during current charging, and the previous moment is a moment at which the charging curve is obtained during last charging.

In some embodiments, the interval between the current moment and the previous moment is a preset interval, that is, the current moment is a moment of the previous moment plus the preset interval. The preset interval may be set according to actual requirements, for example, may be 3 months.

A quantity of cells may be set according to actual requirements and is not limited herein.

In some embodiments, the cell may be a power battery, and the battery management apparatus may be applied to a vehicle, for example, a pure electric vehicle or a hybrid vehicle. In some other embodiments, the cell may be an energy storage battery, and the battery management apparatus may be applied to an energy storage power station, a peak regulation and frequency modulation power auxiliary service, and the like.

In step S106, when the maximum target equivalent self-discharge value and the minimum target equivalent self-discharge value among the target equivalent self-discharge values of all cells are determined, by comparing the obtained target equivalent self-discharge values of all cells, the maximum target equivalent self-discharge value and the minimum target equivalent self-discharge value are determined.

In step S108, the preset threshold may be set according to actual requirements, and is not limited herein.

Steps S106 to S108 are further described in detail below by taking a battery management apparatus including eight cells as an example.

A set of the target equivalent self-discharge values of all cells in the battery management apparatus is {2, 3, 2, 3, 1, 6, 3, 3}. By comparing the target equivalent self-discharge values of all cells, it is determined that the minimum target equivalent self-discharge value is 1, and the maximum target equivalent self-discharge value is 6. A value of the interval is preset to 2, the maximum target equivalent self-discharge value is divided by the interval to obtain a maximum equivalent self-discharge rate (3), and the minimum target equivalent self-discharge value is divided by the interval to obtain a minimum equivalent self-discharge rate (0.5). When it is determined that a difference (2.5) between the maximum equivalent self-discharge rate and the minimum equivalent self-discharge rate is greater than a preset threshold (preset to 2), a target cell corresponding to the maximum target equivalent self-discharge value is managed, that is, a cell with a target equivalent self-discharge value of 6 is managed.

In the battery management method provided in this embodiment of the present disclosure, by obtaining the current high-voltage inflection point power value of the charging curve of each cell and the current historical cumulative balance power value, the current equivalent self-discharge value of each cell is obtained. The target equivalent self-discharge value of each cell is obtained by subtracting the equivalent self-discharge value at the previous moment from the current equivalent self-discharge value, so that self-discharge conditions of all cells are monitored during the use of the battery management apparatus. Then the maximum equivalent self-discharge rate and the minimum equivalent self-discharge rate are obtained through calculation by using the target equivalent self-discharge values of all cells, and when the difference between the maximum equivalent self-discharge rate and the minimum equivalent self-discharge rate is greater than the preset threshold, the target cell with the maximum equivalent self-discharge rate is managed, so that a user can promptly discover a cell with abnormal self-discharge to perform maintenance or replacement.

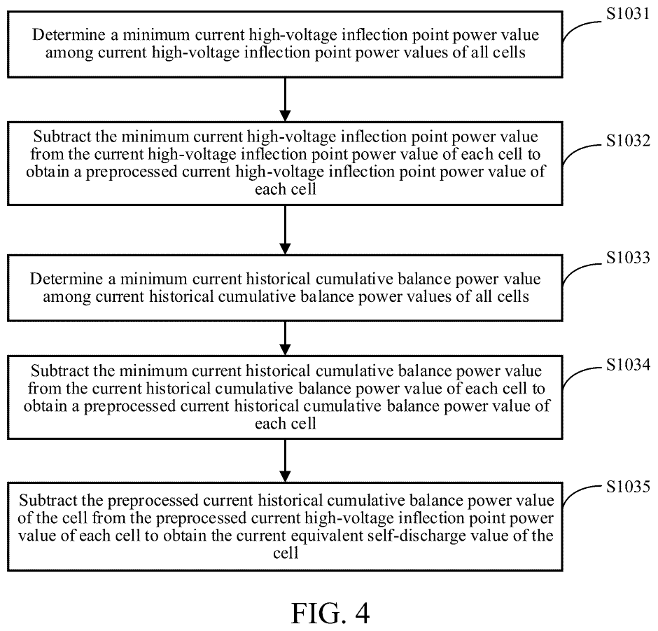

Refer to FIG. 4. FIG. 4 is a sub-flowchart of step S103 in FIG. 1. In some embodiments, as shown in FIG. 4, that the current equivalent self-discharge value of the cell is obtained according to the current high-voltage inflection point power value of each cell and the current historical cumulative balance power value of the cell includes:

S1031: A minimum current high-voltage inflection point power value among the current high-voltage inflection point power values of all cells is determined.

S1032: The minimum current high-voltage inflection point power value is subtracted from the current high-voltage inflection point power value of each cell to obtain a preprocessed current high-voltage inflection point power value of each cell.

S1033: A minimum current historical cumulative balance power value among the current historical cumulative balance power values of all cells is determined.

S1034: The minimum current historical cumulative balance power value is subtracted from the current historical cumulative balance power value of each cell to obtain a preprocessed current historical cumulative balance power value of each cell.

S1035: The preprocessed current historical cumulative balance power value of the cell is subtracted from the preprocessed current high-voltage inflection point power value of each cell to obtain the current equivalent self-discharge value of the cell.

When the minimum current high-voltage inflection point power value among the current high-voltage inflection point power values of all cells is determined, the obtained current high-voltage inflection point power values of all cells are compared to determine the minimum current high-voltage inflection point power value.

When the minimum current historical cumulative balance power value among the current historical cumulative balance power values of all cells is determined, the obtained current historical cumulative balance power values of all cells are compared to determine the minimum current historical cumulative balance power value.

Steps S1031 to S1035 are further described in detail below by taking a battery management apparatus including eight cells as an example.

A set of the current high-voltage inflection point power values of all cells in the battery management apparatus is {4, 6, 8, 5, 1, 7, 5, 3}. By comparing the current high-voltage inflection point power values of all cells, it is determined that the minimum current high-voltage inflection point power value is 1; the minimum current high-voltage inflection point power value is subtracted from the current high-voltage inflection point power value of each cell to obtain a preprocessed current high-voltage inflection point power value of each cell, so that a set of preprocessed current high-voltage inflection point power values of all cells {3, 5, 7, 4, 0, 6, 4, 2} may be obtained; a set of the current historical cumulative balance power values of all cells in the battery management apparatus is {2, 4, 5, 6, 3, 4, 5, 3}. By comparing the current historical cumulative balance power values of all cells, it is determined that the minimum current historical cumulative balance power value is 2; the minimum current historical cumulative balance power value is subtracted from the current historical cumulative balance power value of each cell to obtain a preprocessed current historical cumulative balance power value of each cell, so that a set of the preprocessed current historical cumulative balance power values of all cells {0, 2, 3, 4, 1, 2, 3, 1} may be obtained; and the preprocessed current historical cumulative balance power value of the cell is subtracted from the preprocessed current high-voltage inflection point power value of each cell to obtain the current equivalent self-discharge value of the cell, so that a set of the current equivalent self-discharge values of all cells {3, 2, 4, 0, −1, 4, 1, 1} may be obtained.

Therefore, in some embodiments, preprocessing is performed such as normalizing the current high-voltage inflection point power values of all cells and normalizing the current historical cumulative balance power values of all cells, that is, the minimum current high-voltage inflection point power value is subtracted from the current high-voltage inflection point power value of each cell to obtain the preprocessed current high-voltage inflection point power value of each cell and the minimum current historical cumulative balance power value is subtracted from the current historical cumulative balance power value of each cell to obtain the preprocessed current historical cumulative balance power value of each cell, and then the preprocessed current historical cumulative balance power value is subtracted from the preprocessed current high-voltage inflection point power value to obtain the current equivalent self-discharge value, so that the space required to store the current equivalent self-discharge value may be reduced, and the requirements for the memory may be reduced, thereby saving the cost.

In some other embodiments, that the current equivalent self-discharge value of the cell is obtained according to the current high-voltage inflection point power value of each cell and the current historical cumulative balance power value of the cell includes: the current historical cumulative balance power value of the cell is subtracted from the current high-voltage inflection point power value of each cell to obtain the current equivalent self-discharge value of the cell. That is, in another embodiment, there is no need to preprocess the current high-voltage inflection point power value and the current historical cumulative balance power value. The current historical cumulative balance power value is directly subtracted from the current high-voltage inflection point power value to obtain the current equivalent self-discharge value, so that a number of operations may be reduced, and battery power is saved.

In some embodiments, the battery management apparatus is applied to a vehicle, and that the target cell corresponding to the maximum target equivalent self-discharge value is managed includes: information about the target cell is sent to the vehicle and/or a terminal that is communicatively connected to the vehicle.

The information about the target cell may include a number, a location, the target equivalent self-discharge value, and an equivalent self-discharge rate of the target cell, and the information about the target cell is sent to the vehicle or/or a terminal in communicatively connected to the vehicle. For example, the terminal is a mobile phone of the user. When the vehicle receives the information, a display of the vehicle is controlled to display the information and send an early warning signal, and/or when the terminal receives the information, the information is displayed and the early warning signal is sent to remind the user to maintain or replace the target cell as soon as possible.

In the battery management method provided in this embodiment of the present disclosure, when it is determined that a difference between the maximum equivalent self-discharge rate and the minimum equivalent self-discharge rate is greater than a preset threshold, the information about the target cell corresponding to the maximum target equivalent self-discharge value is sent to the vehicle and/or the terminal communicatively connected to the vehicle, so that the user is informed of the information about the cell with abnormal self-discharge and the user is reminded, to allow the user to take timely measures against the abnormal cell.

In some embodiments, the battery management apparatus further includes a plurality of reminder modules, each reminder module corresponds to a cell, and that the target cell corresponding to the maximum target equivalent self-discharge value is managed further includes: a reminder module corresponding to the target cell is controlled to issue an early warning signal. The reminder module corresponding to the target cell is controlled to issue the early warning signal, so that the user may promptly discover the cell with abnormal self-discharge to preform maintenance or replacement.

The reminder module may be a buzzer component, a voice component, a warning light, and the like.

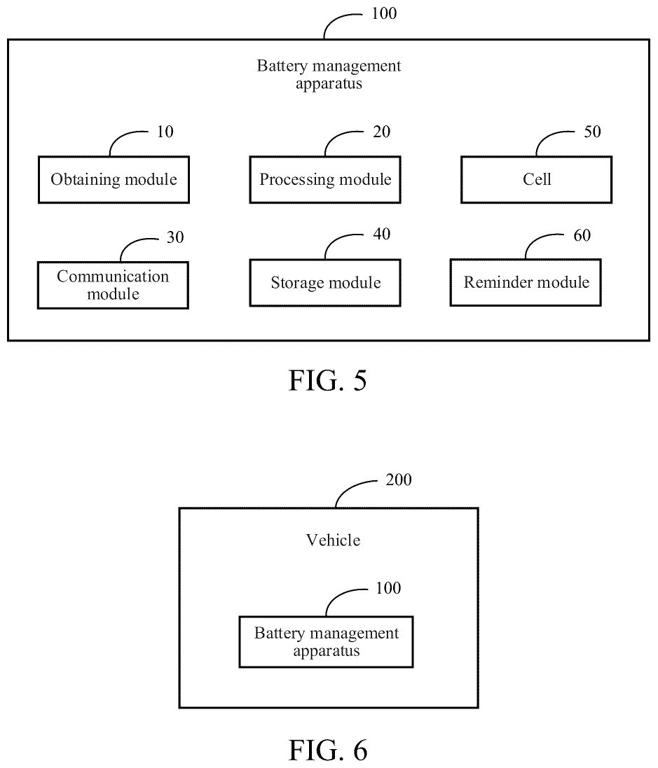

In some embodiments, the battery management method further includes: the equivalent self-discharge value at the previous moment of the cell is replaced with the current equivalent self-discharge value of each cell to update a stored self-discharge value of the cell. The self-discharge value of each cell is stored in a storage module 40 of a battery management apparatus 100 shown in FIG. 5. The equivalent self-discharge value at the previous moment is replaced with the current equivalent self-discharge value for calculation of a target equivalent self-discharge value at a next moment. The next time the target equivalent self-discharge value is calculated, the current equivalent self-discharge value is the foregoing equivalent self-discharge value at the previous moment.

In some embodiments, that the equivalent self-discharge value at the previous moment of the cell is replaced with the current equivalent self-discharge value of each cell to update the stored self-discharge value of the cell includes: a minimum current equivalent self-discharge value among current equivalent self-discharge values of all cells is determined; the minimum current equivalent self-discharge value is subtracted from the current equivalent self-discharge value of each cell to obtain a preprocessed current equivalent self-discharge value of each cell; and the equivalent self-discharge value at the previous moment of the cell is replaced with the preprocessed current equivalent self-discharge value of each cell to update the stored equivalent self-discharge value of the cell. The next time the target equivalent self-discharge value is calculated, the preprocessed current equivalent self-discharge value is the foregoing equivalent self-discharge value at the previous moment.

The foregoing steps are further described in detail below by taking a battery management apparatus including eight cells as an example.

A set of the current equivalent self-discharge values of all cells in the battery management apparatus is {5, 7, 4, 3, 2, 7, 8, 4}. By comparing the current equivalent self-discharge values of all cells, it is determined that the minimum current equivalent self-discharge value is 2; the minimum current equivalent self-discharge value is subtracted from the current equivalent self-discharge value of each cell to obtain a preprocessed current equivalent self-discharge value of each cell, so that an obtained set of the preprocessed current equivalent self-discharge values of all cells is {3, 5, 2, 1, 0, 5, 6, 2}; and the set of the equivalent self-discharge values at the previous moment of all cells is replaced with the set of the preprocessed current equivalent self-discharge values of all cells.

In the battery management method provided in this embodiment of the present disclosure, normalized preprocessing is performed on the current equivalent self-discharge values of all cells, that is, the minimum current equivalent self-discharge value of the cell is subtracted from the current equivalent self-discharge value of each cell to obtain the preprocessed current equivalent self-discharge values of all cells, and then the preprocessed current equivalent self-discharge values of all cells are stored, so that the space required to store the preprocessed current equivalent self-discharge values may be reduced, and the requirements for the memory may be reduced, thereby saving the cost.

Refer to FIG. 5. FIG. 5 is a block diagram of a structure of a battery management apparatus 100 according to an embodiment of the present disclosure. As shown in FIG. 5, the battery management apparatus 100 includes a number of cells 50, an obtaining module 10, and a processing module 20. The obtaining module 10 is configured to obtain a current high-voltage inflection point power value corresponding to a high-voltage inflection point of a charging curve of each cell 50 at a current moment, a current historical cumulative balance power value of each cell 50 at the current moment, and an equivalent self-discharge value at a previous moment of each cell 50. The processing module 20 is configured to obtain a current equivalent self-discharge value of the cell 50 according to the current high-voltage inflection point power value of each cell 50 and the current historical cumulative balance power value of the cell 50; subtract the equivalent self-discharge value at the previous moment of the cell 50 from the current equivalent self-discharge value of each cell 50 to obtain a target equivalent self-discharge value of the cell 50 within an interval between the current moment and the previous moment; determine a maximum target equivalent self-discharge value and a minimum target equivalent self-discharge value among the target equivalent self-discharge values of all cells 50; divide the maximum target equivalent self-discharge value by the interval to obtain a maximum equivalent self-discharge rate, and divide the minimum target equivalent self-discharge value by the interval to obtain a minimum equivalent self-discharge rate; and when it is determined that a difference between the maximum equivalent self-discharge rate and the minimum equivalent self-discharge rate is greater than a preset threshold, manage a target cell 50 corresponding to the maximum target equivalent self-discharge value.

In some embodiments, the obtaining module 10 and the processing module 20 may be processing chips such as a processor, a microcontroller, a controller, and the like, and the obtaining module 10 and the processing module 20 may be separate processing chips or an integrated processing chip.

In the battery management apparatus 100 provided in this embodiment of the present disclosure, by obtaining the current high-voltage inflection point power value of the charging curve of each cell 50 and the current historical cumulative balance power value, the current equivalent self-discharge value of each cell 50 is obtained. The target equivalent self-discharge value of each cell 50 is obtained by subtracting the equivalent self-discharge value at the previous moment from the current equivalent self-discharge value, so that self-discharge conditions of all cells 50 are monitored during the use of the battery management apparatus 100. Then the maximum equivalent self-discharge rate and the minimum equivalent self-discharge rate are obtained through calculation by using the target equivalent self-discharge values of all cells 50, and when the difference between the maximum equivalent self-discharge rate and the minimum equivalent self-discharge rate is greater than the preset threshold, the target cell 50 with the maximum equivalent self-discharge rate is managed, so that a user can promptly discover a cell with abnormal self-discharge to perform maintenance or replacement.

In some embodiments, that the current equivalent self-discharge value of the cell 50 is obtained according to the current high-voltage inflection point power value of each cell 50 and the current historical cumulative balance power value of the cell 50 includes: the processing module 20 determines a minimum current high-voltage inflection point power value among current high-voltage inflection point power values of all cells 50; subtracts the minimum current high-voltage inflection point power value from the current high-voltage inflection point power value of each cell 50 to obtain a preprocessed current high-voltage inflection point power value of each cell 50; determines a minimum current historical cumulative balance power value among current historical cumulative balance power values of all cells 50; subtracts the minimum current historical cumulative balance power value from the current historical cumulative balance power value of each cell 50 to obtain a preprocessed current historical cumulative balance power value of each cell 50; and subtracts the preprocessed current historical cumulative balance power value of the cell 50 from the preprocessed current high-voltage inflection point power value of each cell 50 to obtain the current equivalent self-discharge value of the cell 50.

The battery management apparatus 100 provided in the embodiments of the present disclosure performs preprocessing such as normalizing the current high-voltage inflection point power values of all cells 50 and normalizing the current historical cumulative balance power values of all cells 50, that is, the minimum current high-voltage inflection point power value is subtracted from the current high-voltage inflection point power value of each cell 50 to obtain a preprocessed current high-voltage inflection point power value of each cell 50; the minimum current historical cumulative balance power value is subtracted from the current historical cumulative balance power value of each cell 50 to obtain a preprocessed current historical cumulative balance power value of each cell 50; and then the preprocessed current historical cumulative balance power value is subtracted from the preprocessed current high-voltage inflection point power value to obtain the current equivalent self-discharge value, so that the space required to store the current equivalent self-discharge value may be reduced, and the requirements for the memory may be reduced, thereby saving the cost.

In some other embodiments, that the current equivalent self-discharge value of the cell 50 is obtained according to the current high-voltage inflection point power value of each cell 50 and the current historical cumulative balance power value of the cell 50 includes: the processing module 20 subtracts the current historical cumulative balance power value of the cell 50 from the current high-voltage inflection point power value of each cell 50 to obtain the current equivalent self-discharge value of the cell 50. That is, in another embodiment, there is no need to preprocess the current high-voltage inflection point power value and the current historical cumulative balance power value. The current historical cumulative balance power value is directly subtracted from the current high-voltage inflection point power value to obtain the current equivalent self-discharge value, so that a number of operations may be reduced, and battery power is saved.

In some embodiments, the battery management apparatus 100 is applied to a vehicle. As shown in FIG. 5, the battery management apparatus 100 further includes a communication module 30 configured to communicate with the vehicle, and the managing a target cell 50 corresponding to the maximum target equivalent self-discharge value includes: through the communication module 30, information about the target cell 50 is sent to the vehicle and/or a terminal that is communicatively connected to the vehicle.

The battery management apparatus 100 may send the number, the location, the target equivalent self-discharge value, and the equivalent self-discharge rate of the target cell 50 to the vehicle and/or the terminal communicatively connected to the vehicle through the communication module 30, so that the user may promptly discover the cell with abnormal self-discharge and maintain or replace it.

In some embodiments, the battery management apparatus 100 further includes a number of reminder modules 60, each reminder module 60 corresponds to a cell 50, and the managing a target cell 50 corresponding to the maximum target equivalent self-discharge value includes: a reminder module 60 corresponding to the target cell 50 is controlled to issue an early warning signal.

In some embodiments, the reminder module 60 may be a buzzer component, a voice component, a warning light, and the like.

When it is determined that a difference between the maximum equivalent self-discharge rate and the minimum equivalent self-discharge rate is greater than a preset threshold, the processing module 20 determines the target cell 50 corresponding to the maximum equivalent self-discharge rate and controls the reminder module 60 corresponding to the target cell 50 to issue the early warning signal. Exemplarily, the number of cells are numbered in advance, and the number of reminder modules 60 have numbers corresponding to the numbers of the number of cells. When the difference between the maximum equivalent self-discharge rate and the minimum equivalent self-discharge rate is greater than a preset threshold, the processing module 20 determines the number of the target cell 50 and controls the reminder module 60 with the same number of the target cell 50 to issue the early warning signal, for example, a buzzer, a voice broadcast, a warning light flashing, and the like to remind the user that the self-discharge abnormality occurs in the cell and inform the user of the number of the cell with abnormal self-discharge, so that the user may identify the location of the cell with abnormal self-discharge and maintain or replace it in time.

In some embodiments, as shown in FIG. 5, the battery management apparatus 100 further includes a storage module 40. The storage module 40 stores a self-discharge value of each cell 50. The processing module 20 is further configured to replace the equivalent self-discharge value at the previous moment of the cell 50 with the current equivalent self-discharge value of each cell 50 to update the self-discharge value of the cell 50 stored in the storage module 40 for calculation of the target equivalent self-discharge value at the next moment. The next time the target equivalent self-discharge value is calculated, the current equivalent self-discharge value is the foregoing equivalent self-discharge value at the previous moment.

In some embodiments, the replacing the equivalent self-discharge value at the previous moment of the cell 50 with the current equivalent self-discharge value of each cell 50 to update the self-discharge value of the cell 50 stored in the storage module 40 includes: a minimum current equivalent self-discharge value among current equivalent self-discharge values of all cells is determined; the minimum current equivalent self-discharge value is subtracted from the current equivalent self-discharge value of each cell 50 to obtain a preprocessed current equivalent self-discharge value of each cell 50; and the equivalent self-discharge value at the previous moment of the cell 50 is replaced with the preprocessed current equivalent self-discharge value of each cell 50 to update the stored equivalent self-discharge value of the cell 50. The next time the target equivalent self-discharge value is calculated, the preprocessed current equivalent self-discharge value is the foregoing equivalent self-discharge value at the previous moment.

In some embodiments, the storage module 40 further stores the charging curve of each cell 50 at the current moment and the current high-voltage inflection point power value, so that the obtaining module 10 may obtain the current high-voltage inflection point power value of each cell 50 at the current moment.

In some embodiments, the storage module 40 further stores the current historical cumulative balance power value of each cell 50 at the current moment, so that the obtaining module 10 may obtain the current high-voltage inflection point power value of each cell 50 at the current moment.

The storage module 40 may be a non-volatile memory, such as an FRAM (Ferroelectric Random Access Memory), an EEPROM (Electrically Erasable Programmable Read Only Memory), an EPROM (Erasable Programmable Read Only Memory), and the like.

In the battery management apparatus 100 provided in this embodiment of the present disclosure, normalized preprocessing is performed on the current equivalent self-discharge values of all cells 50, that is, the minimum current equivalent self-discharge value of the cell 50 is subtracted from the current equivalent self-discharge value of each cell 50 to obtain a preprocessed current equivalent self-discharge value of each cell 50, and then the preprocessed current equivalent self-discharge values of all cells 50 are stored, so that the space required to store the preprocessed current equivalent self-discharge values may be reduced, and the requirements for the memory may be reduced, thereby saving the cost.

The battery management apparatus 100 corresponds to the foregoing battery management method. For a more detailed description, reference may be made to the content of each embodiment of the foregoing battery management method. The contents of the battery management apparatus 100 and the foregoing battery management method may also be referred to each other.

Refer to FIG. 6, FIG. 6 is a block diagram of a structure of a vehicle 200 according to an embodiment of the present disclosure. As shown in FIG. 6, the vehicle 200 includes the battery management apparatus 100 provided in any of the foregoing embodiments.

The vehicle 200 may be a pure electric vehicle, a hybrid vehicle, and the like, such as a pure electric vehicle, a pure electric truck, a hybrid truck, and the like.

An embodiment of the present disclosure further provides a computer-readable storage medium. The computer-readable storage medium stores a computer program, and the computer program is invoked by a processor to perform the foregoing battery management method provided in any of the foregoing embodiments.

A person of ordinary skill in the art may understand that all or some of the steps of the various methods in the foregoing embodiments may be implemented by a program instructing relevant hardware. The program may be stored in a computer-readable member. The storage member may include: a flash disk, a read-only memory, a random access device, a magnetic disk, an optical disk, or the like.

It should be noted that for ease of description, the foregoing method embodiments are described as a series of action combinations. However, persons skilled in the art should know that the present disclosure is not limited to the described order of the actions because some steps may be performed in another order or performed at the same time according to the present disclosure. In addition, a person skilled in the art is also to learn that the embodiments described in this specification are all exemplary embodiments, and the involved actions and modules are not necessarily required to the present disclosure.

In the foregoing embodiments, the descriptions of each embodiment have different focuses, and for a part that is not described in detail in an embodiment, reference may be made to the relevant description of other embodiments.

It should be noted that the foregoing descriptions are merely preferred embodiments of the present disclosure, and a person of ordinary skill in the art may make various improvements and modifications without departing from the spirit of the present disclosure. All such improvements and refinements shall fall within the protection scope of the present disclosure.

What is claimed is:

1. A battery management method, applied to a battery management apparatus, the battery management apparatus comprising a plurality of cells, and the battery management method comprising the following steps:
obtaining a current high-voltage inflection point power value corresponding to a high-voltage inflection point of a charging curve of each cell at a current moment;
obtaining a current historical cumulative balance power value of each cell at the current moment;
obtaining a current equivalent self-discharge value of the cell according to the current high-voltage inflection point power value of each cell and the current historical cumulative balance power value of the cell;
obtaining an equivalent self-discharge value at a previous moment of each cell;
subtracting the equivalent self-discharge value at the previous moment of the cell from the current equivalent self-discharge value of each cell to obtain a target equivalent self-discharge value of the cell within an interval between the current moment and the previous moment;
determining a maximum target equivalent self-discharge value and a minimum target equivalent self-discharge value among the target equivalent self-discharge values of all cells;
dividing the maximum target equivalent self-discharge value by the interval to obtain a maximum equivalent self-discharge rate, and dividing the minimum target equivalent self-discharge value by the interval to obtain a minimum equivalent self-discharge rate; and
when it is determined that a difference between the maximum equivalent self-discharge rate and the minimum equivalent self-discharge rate is greater than a preset threshold, managing a target cell corresponding to the maximum target equivalent self-discharge value.

2. The battery management method according to claim 1, the obtaining a current equivalent self-discharge value of the cell according to the current high-voltage inflection point power value of each cell and the current historical cumulative balance power value of the cell comprising:
subtracting the current historical cumulative balance power value of the cell from the current high-voltage inflection point power value of each cell to obtain the current equivalent self-discharge value of the cell.

3. The battery management method according to claim 1, the obtaining a current equivalent self-discharge value of the cell according to the current high-voltage inflection point power value of each cell and the current historical cumulative balance power value of the cell comprising:
determining a minimum current high-voltage inflection point power value among current high-voltage inflection point power values of all cells;
subtracting the minimum current high-voltage inflection point power value from the current high-voltage inflection point power value of each cell to obtain a preprocessed current high-voltage inflection point power value of each cell;
determining a minimum current historical cumulative balance power value among current historical cumulative balance power values of all cells;
subtracting the minimum current historical cumulative balance power value from the current historical cumulative balance power value of each cell to obtain a preprocessed current historical cumulative balance power value of each cell; and
subtracting the preprocessed current historical cumulative balance power value of the cell from the preprocessed current high-voltage inflection point power value of each cell to obtain the current equivalent self-discharge value of the cell.

4. The battery management method according to claim 1, the battery management apparatus being applied to a vehicle, and the managing a target cell corresponding to the maximum target equivalent self-discharge value comprising:
sending information about the target cell to the vehicle and/or a terminal that is communicatively connected to the vehicle.

5. The battery management method according to claim 4, the information about the target cell comprising a number, a location, the target equivalent self-discharge value, and an equivalent self-discharge rate of the target cell.

6. The battery management method according to claim 1, wherein the battery management apparatus further comprises a plurality of reminder modules, each reminder module corresponds to a cell, and the managing a target cell corresponding to the maximum target equivalent self-discharge value further comprises:
controlling a reminder module corresponding to the target cell to issue an early warning signal.

7. The battery management method according to claim 1, further comprising: replacing the equivalent self-discharge value at the previous moment of the cell with the current equivalent self-discharge value of each cell to update a stored equivalent self-discharge value of the cell.

8. The battery management method according to claim 7, the replacing the equivalent self-discharge value at the previous moment of the cell with the current equivalent self-discharge value of each cell to update a stored equivalent self-discharge value of the cell comprising:
determining a minimum current equivalent self-discharge value among current equivalent self-discharge values of all cells;
subtracting the minimum current equivalent self-discharge value from the current equivalent self-discharge value of each cell to obtain a preprocessed current equivalent self-discharge value of each cell; and
replacing the equivalent self-discharge value at the previous moment of the cell with the preprocessed current equivalent self-discharge value of each cell to update the stored equivalent self-discharge value of the cell.

9. The battery management method according to claim 1, wherein the previous moment is a moment at which the vehicle leaves a factory, the equivalent self-discharge value at the previous moment of each cell is 0, the historical cumulative balance power value at the previous moment of each cell is 0, and the high-voltage inflection point power value at the previous moment of each cell is 0.

10. The battery management method according to claim 1, wherein when the current moment is current charging, a moment of the charging curve is obtained, and when the previous moment is previous charging, a moment of the charging curve is obtained.

11. The battery management method according to claim 1, wherein the cell is a power battery or an energy storage battery.

12. A battery management apparatus, the battery management apparatus comprising a plurality of cells, and further comprising:
an obtaining module, configured to obtain a current high-voltage inflection point power value corresponding to a high-voltage inflection point of a charging curve of each cell at a current moment, a current historical cumulative balance power value of each cell at the current moment, and an equivalent self-discharge value at a previous moment of each cell; and
a processing module, configured to obtain a current equivalent self-discharge value of the cell according to the current high-voltage inflection point power value of each cell and the current historical cumulative balance power value of the cell; subtract the equivalent self-discharge value at the previous moment of the cell from the current equivalent self-discharge value of each cell to obtain a target equivalent self-discharge value of the cell within an interval between the current moment and the previous moment; determine a maximum target equivalent self-discharge value and a minimum target equivalent self-discharge value among the target equivalent self-discharge values of all cells; divide the maximum target equivalent self-discharge value by the interval to obtain a maximum equivalent self-discharge rate, and divide the minimum target equivalent self-discharge value by the interval to obtain a minimum equivalent self-discharge rate; and when it is determined that a difference between the maximum equivalent self-discharge rate and the minimum equivalent self-discharge rate is greater than a preset threshold, manage a target cell corresponding to the maximum target equivalent self-discharge value.

13. The battery management apparatus according to claim 12, when configured to obtain a current equivalent self-discharge value of the cell according to the current high-voltage inflection point power value of each cell and the current historical cumulative balance power value of the cell, the processing module being specifically configured to:
subtract the current historical cumulative balance power value of the cell from the current high-voltage inflection point power value of each cell to obtain the current equivalent self-discharge value of the cell.

14. The battery management apparatus according to claim 12, when configured to obtain a current equivalent self-discharge value of the cell according to the current high-voltage inflection point power value of each cell and the current historical cumulative balance power value of the cell, the processing module being specifically configured to:
determine a minimum current high-voltage inflection point power value among current high-voltage inflection point power values of all cells;
subtract the minimum current high-voltage inflection point power value from the current high-voltage inflection point power value of each cell to obtain a preprocessed current high-voltage inflection point power value of each cell;
determine a minimum current historical cumulative balance power value among current historical cumulative balance power values of all cells;
subtract the minimum current historical cumulative balance power value from the current historical cumulative balance power value of each cell to obtain a preprocessed current historical cumulative balance power value of each cell; and
subtract the preprocessed current historical cumulative balance power value of the cell from the preprocessed current high-voltage inflection point power value of each cell to obtain the current equivalent self-discharge value of the cell.

15. The battery management apparatus according to claim 12, the battery management apparatus being applied to a vehicle, the battery management apparatus further comprising a communication module configured to communicate with the vehicle, and when configured to manage a target cell corresponding to the maximum target equivalent self-discharge value, the processing module being specifically configured to:
send, through the communication module, information about the target cell to the vehicle and/or a terminal that is communicatively connected to the vehicle.

16. The battery management apparatus according to claim 12, further comprising a plurality of reminder modules, each reminder module corresponding to a cell, and when configured to manage a target cell corresponding to the maximum target equivalent self-discharge value, the processing module being specifically configured to:
control the reminder module corresponding to the target cell to issue an early warning signal.

17. The battery management apparatus according to claim 12, further comprising a storage module, the storage module storing the equivalent self-discharge value of each cell, and the processing module being further configured to replace the equivalent self-discharge value at the previous moment of the cell with the current equivalent self-discharge value of each cell to update a stored self-discharge value of the cell.

18. The battery management apparatus according to claim 17, when configured to replace the equivalent self-discharge value at the previous moment of the cell with the current equivalent self- discharge value of each cell to update a stored equivalent self-discharge value of the cell, the processing module being specifically configured to
determine a minimum current equivalent self-discharge value among current equivalent self-discharge values of all cells;
subtract the minimum current equivalent self-discharge value from the current equivalent self-discharge value of each cell to obtain a preprocessed current equivalent self-discharge value of each cell; and
replace the equivalent self-discharge value at the previous moment of the cell with the preprocessed current equivalent self-discharge value of each cell to update the stored equivalent self-discharge value of the cell.

19. A computer-readable storage medium, storing a computer program, the computer program being invoked by a processor to perform the following steps:
obtaining a current high-voltage inflection point power value corresponding to a high-voltage inflection point of a charging curve of each cell among a plurality of cells at a current moment;
obtaining a current historical cumulative balance power value of each cell at the current moment;
obtaining a current equivalent self-discharge value of the cell according to the current high-voltage inflection point power value of each cell and the current historical cumulative balance power value of the cell;
obtaining an equivalent self-discharge value at a previous moment of each cell;
subtracting the equivalent self-discharge value at the previous moment of the cell from the current equivalent self-discharge value of each cell to obtain a target equivalent self-discharge value of the cell within an interval between the current moment and the previous moment;
determining a maximum target equivalent self-discharge value and a minimum target equivalent self-discharge value among the target equivalent self-discharge values of all cells;
dividing the maximum target equivalent self-discharge value by the interval to obtain a maximum equivalent self-discharge rate, and dividing the minimum target equivalent self-discharge value by the interval to obtain a minimum equivalent self-discharge rate; and
when it is determined that a difference between the maximum equivalent self-discharge rate and the minimum equivalent self-discharge rate is greater than a preset threshold, managing a target cell corresponding to the maximum target equivalent self-discharge value.

20. The computer-readable storage medium according to claim 19, in terms of obtaining, according to the current high-voltage inflection point power value of each cell and the current historical cumulative balance power value of the cell, a current equivalent self-discharge value of the cell, the computer program being invoked by the processor to perform the following steps:
determining a minimum current high-voltage inflection point power value among current high-voltage inflection point power values of all cells;
subtracting the minimum current high-voltage inflection point power value from the current high-voltage inflection point power value of each cell to obtain a preprocessed current high-voltage inflection point power value of each cell;
determining a minimum current historical cumulative balance power value among current historical cumulative balance power values of all cells;
subtracting the minimum current historical cumulative balance power value from the current historical cumulative balance power value of each cell to obtain a preprocessed current historical cumulative balance power value of each cell; and
subtracting the preprocessed current historical cumulative balance power value of the cell from the preprocessed current high-voltage inflection point power value of each cell to obtain the current equivalent self-discharge value of the cell.
